(19) United States
(12) Patent Application Publication
(10) Pub. No.: US 2026/0311969 A1
(43) Pub. Date: Oct. 8, 2026

(54) ETCHING METHOD AND PLASMA PROCESSING APPARATUS

(71) Applicant: Tokyo Electron Limited, Tokyo (JP)

(72) Inventor: Takayuki KATSUNUMA, Miyagi (JP)

(73) Assignee: Tokyo Electron Limited, Tokyo (JP)

(21) Appl. No.: 19/457,716

(22) Filed: Jan. 23, 2026

Related U.S. Application Data
(63) Continuation of application No. PCT/JP2024/025935, filed on Jul. 19, 2024.

(30) Foreign Application Priority Data
Aug. 2, 2023 (JP) 2023-126146

(51) Int. Cl. H01J 37/32

(52) U.S. Cl. CPC H01J 37/3244; H01J 37/32715; H01J 2237/334

(57) ABSTRACT

An etching method includes (a) placing a substrate on a substrate support in a chamber, (b) exposing the substrate to a first process gas including a hydrogen fluoride gas, and (c) exposing, after (b), the substrate to plasma generated from a second process gas while providing an electrical bias to the substrate support. The second process gas includes at least one inert gas selected from the group consisting of a noble gas and a nitrogen gas.

### CROSS-REFERENCE TO RELATED APPLICATIONS

This application is a continuation application of PCT Application No. PCT/JP 2024/025935, filed on Jul. 19, 2024, which claims the benefit of priority from Japanese Patent Application No. 2023-126146, filed on Aug. 2, 2023. The entire contents of the above listed PCT and priority applications are incorporated herein by reference.

### BACKGROUND

### Field

Exemplary embodiments of the present disclosure relate to an etching method and a plasma processing device.

### Description of the Related Art

Japanese Unexamined Patent Application Publication No. 2015-173240 describes a method for etching a portion containing silicon oxide. The method includes (a) exposing a substrate including the portion containing silicon oxide to plasma generated from a process gas including a fluorocarbon gas. Step (a) includes etching the portion, and forming a deposit containing a fluorocarbon on the portion. The method includes (b) etching the portion with radicals in the fluorocarbon contained in the deposit. Steps (a) and (b) are repeated alternately.

### SUMMARY

An etching method according to one exemplary embodiment includes (a) placing a substrate on a substrate support in a chamber, (b) exposing the substrate to a first process gas including a hydrogen fluoride gas, and (c) exposing, after (b), the substrate to plasma generated from a second process gas while providing an electrical bias to the substrate support. The second process gas includes at least one inert gas selected from the group consisting of a noble gas and a nitrogen gas.

### BRIEF DESCRIPTION OF THE DRAWINGS

FIG. 1 is a diagram of a plasma processing system, illustrating an example structure.

FIG. 2 is a diagram of an inductively coupled plasma processing device, illustrating an example structure.

FIG. 3 is a flowchart of an etching method according to one exemplary embodiment.

FIG. 4 is a partially enlarged view of an example substrate to be processed with the method in FIG. 3.

FIG. 5 is a cross-sectional view of the substrate undergoing a step in the etching method according to the exemplary embodiment.

FIG. 6 is a cross-sectional view of the substrate undergoing a step in the etching method according to the exemplary embodiment.

FIG. 7 is a partially enlarged plan view of the example substrate to be processed with the method in FIG. 3.

FIG. 8 is a graph showing an example relationship between the number of cycles and the etching amount.

FIG. 9 is a graph showing an example relationship between the type of film and the etching amount.

FIG. 10 is a flowchart of an etching method according to one exemplary embodiment.

FIG. 11 is a cross-sectional view of a substrate undergoing a step in the etching method according to the exemplary embodiment.

FIG. 12 is a cross-sectional view of the substrate undergoing a step in the etching method according to the exemplary embodiment.

FIG. 13 is a cross-sectional view of the substrate undergoing a step in the etching method according to the exemplary embodiment.

FIG. 14 is a timing chart of changes in power and a process gas supplied to the plasma processing device over time in an example.

### DETAILED DESCRIPTION

Various exemplary embodiments will now be described in detail with reference to the drawings. In the figures, like reference numerals denote like or corresponding components.

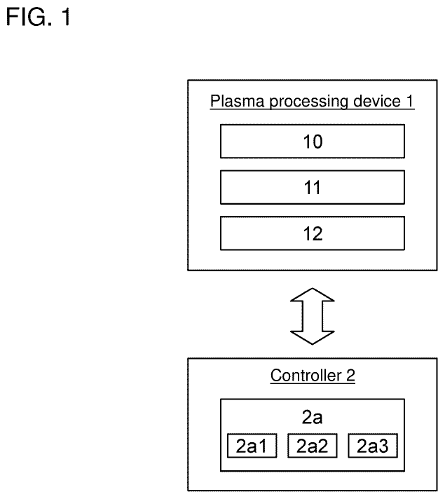

FIG. 1 is a diagram of a plasma processing system, illustrating an example structure. In one embodiment, the plasma processing system includes a plasma processing device 1 and a controller 2. The plasma processing system is an example of a substrate processing system. The plasma processing device 1 is an example of a substrate processing device. The plasma processing device 1 includes a plasma processing chamber 10, a substrate support 11, and a plasma generator 12. The plasma processing chamber 10 has a plasma processing space. The plasma processing chamber 10 also has at least one gas inlet for supplying at least one process gas into the plasma processing space and at least one gas outlet for discharging the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates plasma from at least one process gas supplied into the plasma processing space. The plasma generated in the plasma processing space may be, for example, capacitively coupled plasma (CCP), inductively coupled plasma (ICP), electron cyclotron resonance (ECR) plasma, helicon wave plasma (HWP), or surface wave plasma (SWP). The plasma generator 12 may be one of various plasma generators including an alternating current (AC) plasma generator and a direct current (DC) plasma generator. In one embodiment, an AC signal (AC power) used in the AC plasma generator has a frequency in a range of 100 kHz to 10 GHz. Thus, the AC signal may be a radio-frequency (RF) signal or a microwave signal. In one embodiment, the RF signal has a frequency in a range of 100 kHz to 150 MHz.

The controller 2 processes computer-executable instructions that cause the plasma processing device 1 to perform various steps described in one or more embodiments of the present disclosure. The controller 2 may control the components of the plasma processing device 1 to perform the various steps described herein. In one embodiment, some or all of the components of the controller 2 may be included in the plasma processing device 1. The controller 2 may include a processor 2a1, a storage 2a2, and a communication interface 2a3. The controller 2 is implemented by, for example, a computer 2a. The processor 2a1 may perform various control operations by loading a program from the storage 2a2 and executing the loaded program. The program may be prestored in the storage 2a2 or may be obtained through a medium as appropriate. The obtained program is stored into the storage 2a2 to be loaded from the storage 2a2 and executed by the processor 2a1. The medium may be one of various storage media readable by the computer 2a or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing device 1 through a communication line such as a local area network (LAN).

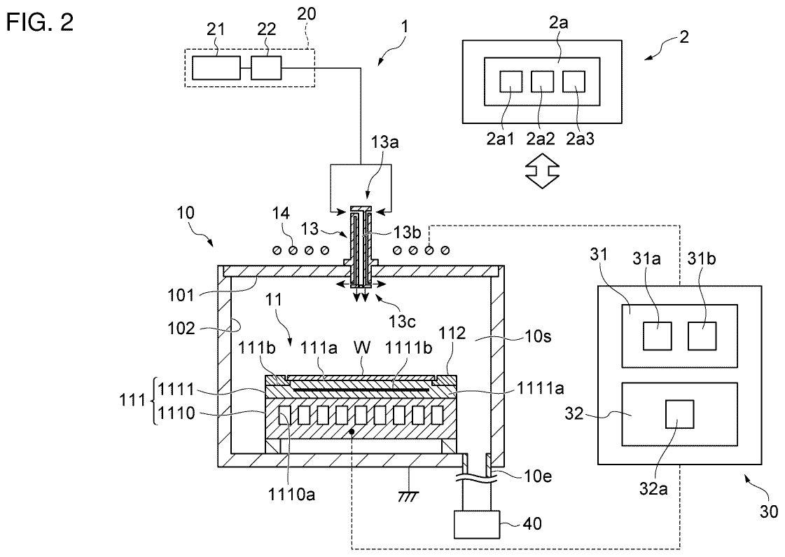

An example structure of an inductively coupled plasma processing device as an example of the plasma processing device 1 will now be described. FIG. 2 is a diagram of the inductively coupled plasma processing device, illustrating an example structure.

The inductively coupled plasma processing device 1 includes the plasma processing chamber 10, the gas supply 20, a power supply 30, and the exhaust system 40. The plasma processing chamber 10 includes a dielectric window 101. The plasma processing device 1 also includes the substrate support 11, a gas guide unit, and an antenna 14. The substrate support 11 is located in the plasma processing chamber 10. The antenna 14 is located on or above the plasma processing chamber 10 (more specifically, on or above the dielectric window 101). The plasma processing chamber 10 has a plasma processing space 10s defined by the dielectric window 101, a sidewall 102 of the plasma processing chamber 10, and the substrate support 11. The plasma processing chamber 10 is grounded.

The substrate support 11 includes a body 111 and a ring assembly 112. The body 111 includes a central portion 111a for supporting a substrate W and an annular portion 111b for supporting the ring assembly 112. A wafer is an example of the substrate W. The annular portion 111b of the body 111 surrounds the central portion 111a of the body 111 as viewed in plan. The substrate W is placeable on the central portion 111a of the body 111. The ring assembly 112 is located on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may function as a bias electrode. The ESC 1111 is located on the base 1110. The ESC 1111 includes a ceramic member 1111a and an electrostatic electrode 1111b located inside the ceramic member 1111a. The ceramic member 1111a includes the central portion 111a. In one embodiment, the ceramic member 1111a also includes the annular portion 111b. The annular portion 111b may be included in another member surrounding the ESC 1111, such as an annular ESC or an annular insulating member. In this case, the ring assembly 112 may be located on the annular ESC or the annular insulating member, or may be located on both the ESC 1111 and the annular insulating member. At least one RF/DC electrode coupled to an RF power supply 31 or a DC power supply 32, or both (described later) may be located inside the ceramic member 1111a. In this case, the RF/DC electrode functions as a bias electrode. The conductive member in the base 1110 and at least one RF/DC electrode may function as multiple bias electrodes. The electrostatic electrode 1111b may also function as a bias electrode. The substrate support 11 thus includes at least one bias electrode.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may include a temperature controller that adjusts the temperature of at least one of the ESC 1111, the ring assembly 112, or the substrate to a target temperature. The temperature controller may include a heater, a heat transfer medium, a channel 1110a, or a combination of these. The channel 1110a carries a heat transfer fluid such as brine or a gas. In one embodiment, the channel 1110a is defined inside the base 1110, and one or more heaters are located inside the ceramic member 1111a in the ESC 1111. The substrate support 11 may include a heat transfer gas supply to supply a heat transfer gas into a space between the back surface of the substrate W and the central portion 111a.

The gas guide unit introduces at least one process gas from the gas supply 20 into the plasma processing space 10s. In one embodiment, the gas guide unit includes a central gas injector (CGI) 13. The CGI 13 is located above the substrate support 11 and installed in a central opening in the dielectric window 101. The CGI 13 has at least one gas inlet 13a, at least one gas channel 13b, and at least one gas guide 13c. The process gas supplied to the gas inlet 13a passes through the gas channel 13b and is introduced into the plasma processing space 10s through the gas guide 13c. In addition to or in place of the CGI 13, the gas guide unit may include one or more side gas injectors (SGIs) installed in one or more openings in the sidewall 102.

The gas supply 20 may include at least one gas source 21 and at least one flow controller 22. In one embodiment, the gas supply 20 supplies at least one process gas from each gas source 21 to the gas guide unit through the corresponding flow controller 22. The flow controller 22 may be, for example, a mass flow controller or a pressure-based flow controller. The gas supply 20 may further include at least one flow rate modulator that causes at least one process gas to be supplied at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one bias electrode and the antenna 14. This generates plasma from at least one process gas supplied into the plasma processing space 10s. The RF power supply 31 may thus function as at least a part of the plasma generator 12. A bias RF signal is provided to at least one bias electrode to generate a bias potential in the substrate W, thus drawing ions in the generated plasma toward the substrate W.

In one embodiment, the RF power supply 31 includes a first RF generator 31a and a second RF generator 31b. The first RF generator 31a is coupled to the antenna 14 through at least one impedance matching circuit to generate a source RF signal (source RF power) for plasma generation. In one embodiment, the source RF signal has a frequency in a range of 10 to 150 MHz. In one embodiment, the first RF generator 31a may generate multiple source RF signals with different frequencies. The one or more generated source RF signals are provided to the antenna 14.

The second RF generator 31b is coupled to at least one bias electrode through at least one impedance matching circuit to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The one or more generated bias RF signals are provided to at least one bias electrode. In various embodiments, at least one of the source RF signal or the bias RF signal may be pulsed.

The power supply 30 may include the DC power supply 32 coupled to the plasma processing chamber 10. The DC power supply 32 includes a bias DC generator 32a. In one embodiment, the bias DC generator 32a is coupled to at least one bias electrode to generate a bias DC signal. The generated bias DC signal is applied to at least one bias electrode.

In various embodiments, the bias DC signal may be pulsed. In this case, a sequence of voltage pulses is applied to at least one bias electrode. The voltage pulses may have rectangular, trapezoidal, or triangular pulse waveforms, or a combination of these. In one embodiment, a waveform generator for generating a sequence of voltage pulses based on DC signals is coupled between the bias DC generator 32a and at least one bias electrode. Thus, the bias DC generator 32a and the waveform generator form a voltage pulse generator. The voltage pulses may have positive polarity or negative polarity. The sequence of voltage pulses may include one or more positive voltage pulses and one or more negative voltage pulses within one cycle. The power supply 30 may include the bias DC generator 32a in addition to the RF power supply 31 or in place of the second RF generator 31b.

The antenna 14 includes one or more coils. In one embodiment, the antenna 14 may include an outer coil and an inner coil that are coaxial with each other. In this case, the RF power supply 31 may be coupled to both the outer coil and the inner coil, or either the outer coil or the inner coil. When the RF power supply 31 is coupled to both the outer coil and the inner coil, a single RF generator may be coupled to both the outer coil and the inner coil, or separate RF generators may be coupled respectively to the outer coil and the inner coil.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may be a turbomolecular pump, a dry pump, or a combination of these.

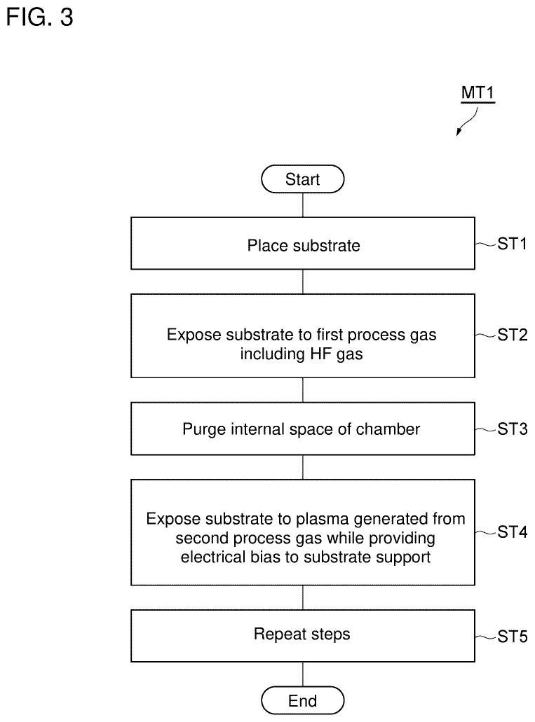

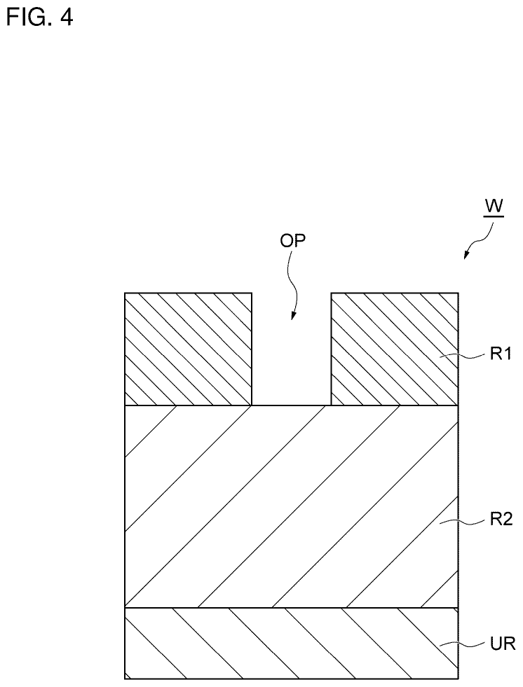

FIG. 3 is a flowchart of an etching method according to one exemplary embodiment. An etching method MT1 (hereafter referred to as a method MT1) shown in FIG. 3 may be implemented by the plasma processing device 1 according to the above embodiment. The method MT1 may be implemented for the substrate W in FIG. 4.

FIG. 4 is a cross-sectional view of an example substrate to be processed with the method in FIG. 3. In one embodiment, the substrate W may include a first portion R1 and a second portion R2 as shown in FIG. 4. The first portion R1 may be a mask. The substrate W may not include the first portion R1. The first portion R1 has at least one opening OP. The opening OP may be a hole or a slit. The first portion R1 may have multiple openings OP. The second portion R2 may be located below the first portion R1. The second portion R2 may be an etching target film. The substrate W may further include an underlying portion UR. The underlying portion UR may be located below the second portion R2. The first portion R1, the second portion R2, and the underlying portion UR may be films.

The first portion R1 contains a first material. The first material may include a metal or silicon. The metal may be other than tungsten, molybdenum, and titanium. The first material may include ruthenium (Ru).

The second portion R2 contains a second material. The second material is different from the first material. The second material may include at least one selected from the group consisting of silicon, carbon, and a metal. The second material may be at least one silicon-containing material selected from the group consisting of silicon oxide (SiOₓ), silicon nitride (SiNₓ), silicon oxynitride (SiON), and polysilicon, where x is a positive real number. The second material may be at least one carbon-containing material selected from the group consisting of a photoresist (polymer) and amorphous carbon. The second material may include at least one metal selected from the group consisting of tungsten (W), molybdenum (Mo), and titanium (Ti). The second material may be a compound containing a metallic element and a nonmetallic element. The second material may be at least one selected from the group consisting of metal silicide, metal nitride, and metal carbide. The second material may be tungsten silicide (WSi).

The underlying portion UR contains a third material. The third material is different from the first material and the second material. The third material may include a metal or silicon.

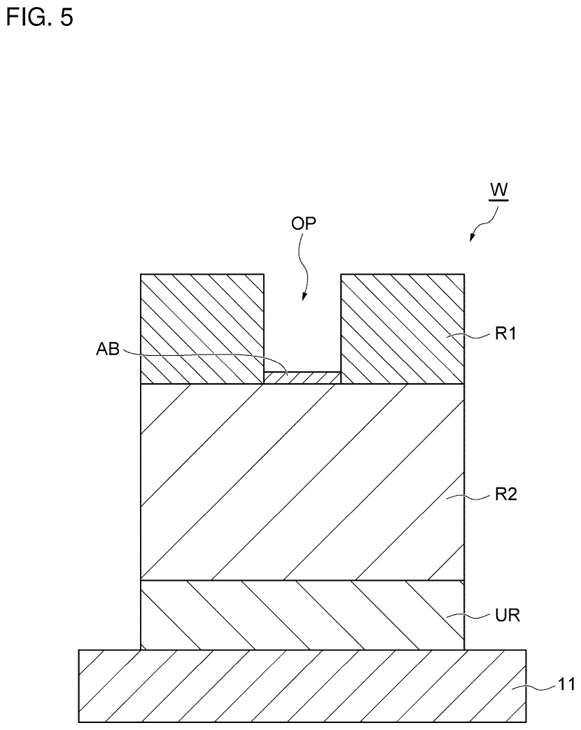

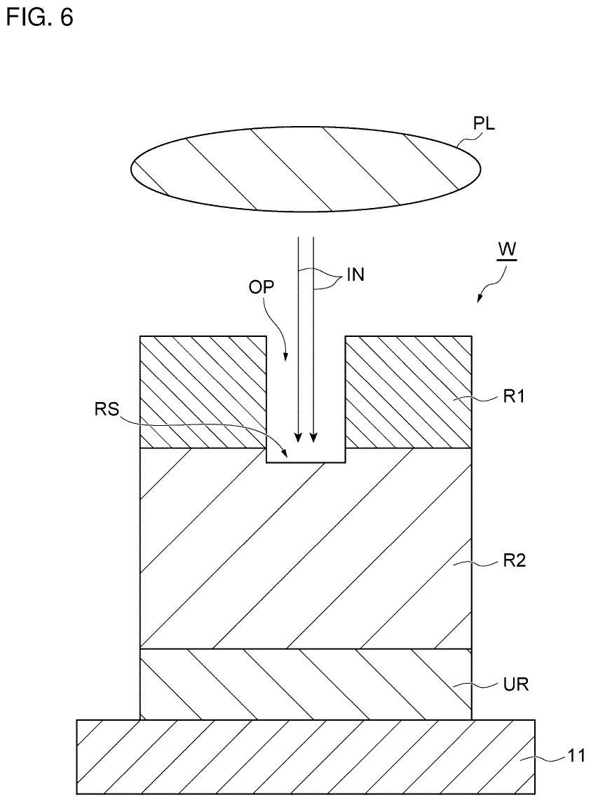

The method MT1 implemented by the plasma processing device 1 according to the above embodiment to process the substrate W will now be described by way of example with reference to FIGS. 3 to 6. FIGS. 5 and 6 are each a cross-sectional view of the substrate undergoing a step in the etching method according to the exemplary embodiment. The components of the plasma processing device 1 are controlled by the controller 2 to allow the plasma processing device 1 to implement the method MT1. With the method MT1, the substrate W is processed on the substrate support 11 located in the plasma processing chamber 10 as shown in FIG. 2.

As shown in FIG. 3, the method MT1 may include steps ST1 to ST5. Steps ST1 to ST5 may be performed sequentially. The method MT1 may not include step ST3 or step ST5.

### Step ST1

In step ST1, the substrate W shown in FIG. 4 is placed on the substrate support 11 in the plasma processing chamber 10.

### Step ST2

In step ST2, the substrate W is exposed to a first process gas including a hydrogen fluoride (HF) gas. In step ST2, plasma may not be generated from the first process gas. At the end of step ST2, supply of the first process gas may be stopped. In step ST2, hydrogen fluoride molecules are adsorbed on the surface of the substrate W to form an adsorption layer AB as shown in FIG. 5. The adsorption layer AB may contain hydrogen fluoride. The hydrogen fluoride molecules are adsorbed on the surface of the second portion R2. The hydrogen fluoride molecules may be or may not be adsorbed on the surface of the first portion R1. The adsorption layer AB may be formed by reaction between the hydrogen fluoride and the second portion R2. The adsorption layer AB may have a thickness that increases over time and remains constant after reaching a specific value.

The first process gas may further include at least one inert gas selected from the group consisting of a noble gas and a nitrogen (N₂) gas. Examples of the noble gas herein include an argon (Ar) gas, a helium (He) gas, a xenon (Xe) gas, and a neon (Ne) gas. The hydrogen fluoride gas may have the highest flow rate of all gases included in the first process gas. The inert gas included in the first process gas may be the same as or different from an inert gas included in a second process gas in step ST4. The first process gas may be free of a fluorine-containing gas other than a hydrogen fluoride gas.

Step ST2 may be performed for a duration of 0.1 to 100 seconds or 30 to 80 seconds.

In step ST2, the temperature of the substrate support 11 may be controlled to be in a range of −10 to 80° C. or 10 to 80° C. In this range, the adsorption of the hydrogen fluoride onto silicon oxide is not facilitated. In step ST4, the silicon oxide is thus etched at a lower etching rate than a silicon nitride.

In step ST2, the plasma processing chamber 10 may have a pressure higher than or equal to 100 mTorr (13 Pa). The plasma processing chamber 10 may have a pressure lower than or equal to 1000 mTorr (130 Pa).

Step ST2 may be performed as described below. The gas supply 20 supplies the first process gas into the plasma processing chamber 10. The controller 2 controls the gas supply 20 and the plasma generator 12 not to allow plasma generation.

### Step ST3

In step ST3, the internal space of the plasma processing chamber 10 is purged. Purging may be performed by supplying an inert gas into the plasma processing chamber 10 or evacuating the internal space of the plasma processing chamber 10. Purging may be performed in combination with supply of an inert gas and evacuation.

### Step ST4

In step ST4, the substrate W is exposed to plasma PL generated from the second process gas while an electrical bias is being provided to the substrate support 11 as shown in FIG. 6. The second process gas may be different from the first process gas in step ST2. The second process gas includes at least one inert gas selected from the group consisting of a noble gas and a nitrogen (N₂) gas. The inert gas may have the highest flow rate of all gases included in the second process gas. The second process gas may be free of a halogen gas.

In step ST4, the electrical bias causes ions IN in the plasma PL to collide with the adsorption layer AB. The ions IN may be ions of the inert gas. The collision energy of the ions IN causes a reaction between the adsorption layer AB and the substrate W (second portion R2), thus etching the substrate W (second portion R2). This forms a recess RS on the substrate W (second portion R2). In step ST4, the etching may be stopped when the adsorption layer AB is depleted. At the end of step ST4, supply of the second process gas may be stopped.

Step ST4 may be performed for a shorter duration than step ST2. Step ST4 may be performed for a duration less than or equal to one-third of the duration of step ST2. Step ST4 may be performed for a duration of 0.1 to 100 seconds or 0.1 to 20 seconds. The electrical bias causes the ions IN to collide with the substrate W (second portion R2), thus producing high collision energy of the ions IN acting on the substrate W (second portion R2). Thus, the etching rate can be still high when step ST4 is performed for a shorter duration.

In step ST4, the temperature of the substrate support 11 may be controlled to be in a range of −10 to 80° C. or 10 to 80° C.

The plasma processing chamber 10 may have a lower pressure in step ST4 than in step ST2. In step ST4, the plasma processing chamber 10 may have a pressure higher than or equal to 10 mTorr (1.3 Pa). The plasma processing chamber 10 may have a pressure lower than or equal to 100 mTorr (13 Pa).

Step ST4 may be performed as described below. The gas supply 20 first supplies the second process gas into the plasma processing chamber 10. The plasma generator 12 then generates the plasma PL from the second process gas in the plasma processing chamber 10. The controller 2 controls the gas supply 20 and the plasma generator 12 to generate the plasma PL. The controller 2 controls the power supply 30 to provide the electrical bias to the substrate support 11.

### Step ST5

In step ST5, steps ST2 to ST4 are repeated. The second portion R2 can thus be etched by a greater degree, allowing the recess RS to be deeper. In step ST2 repeated in step ST5, the adsorption layer AB may be formed on the sidewalls and the bottom of the recess RS. In step ST4 repeated in step ST5, the ions IN collide with the adsorption layer AB on the bottom of the recess RS but are less likely to collide with the adsorption layer AB on the sidewalls of the recess RS.

The above method MT1 can increase the etching rate of the substrate W (second portion R2) in step ST4. The mechanism may be explained as described below but is not limited to this example. In step ST2, the hydrogen fluoride molecules are adsorbed on the surface of the substrate W to form the adsorption layer AB. The adsorption layer AB may be formed by the reaction of the hydrogen fluoride with the substrate W (second portion R2). In step ST4, the electrical bias causes the ions IN in the plasma PL to collide with the adsorption layer AB. The collision energy of the ions IN causes a reaction between the adsorption layer AB and the substrate W (second portion R2), thus etching the substrate W (second portion R2).

With the above method MT1, film deposition is not performed by plasma chemical vapor deposition (CVD) in step ST2. Thus, the critical dimension (CD) and the depth of the recess RS are less susceptible to the loading effects. This improves the uniformity of the CD and the depth of the recess RS in the plane.

With the above method MT1, a deposit is less likely to adhere to the opening OP in step ST2, thus reducing clogging of the opening OP.

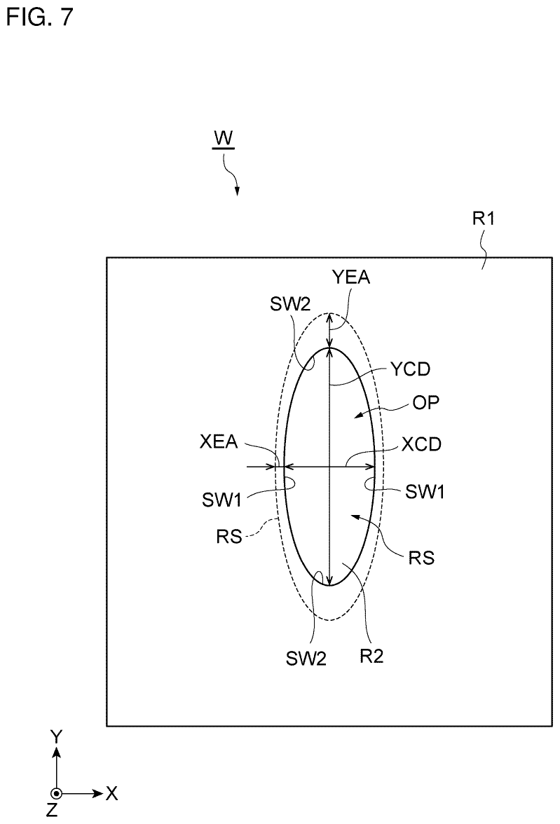

FIG. 7 is a partially enlarged plan view of the example substrate W to be processed with the method MT1. FIG. 7 shows the XYZ orthogonal coordinate system. The first direction X and the second direction Y are along the main surface of the substrate W. The third direction Z is perpendicular to the main surface of the substrate W. The substrate W shown in FIG. 7 includes the second portion R2 as an etching target film. The second portion R2 includes at least one recess RS. The recess RS corresponds to the opening OP in the first portion R1. The recess RS may be formed by etching the second portion R2 through the opening OP before step ST2.

The recess RS includes a pair of first sidewalls SW1 facing each other with a first width XCD between the pair of first sidewalls SW1 in the first direction X and a pair of second sidewalls SW2 facing each other with a second width YCD between the pair of second sidewalls SW2 in the second direction Y. The second direction Y is perpendicular to the first direction X. The second width YCD is greater than the first width XCD. The recess RS may be, for example, oval in an XY plane including the first direction X and the second direction Y.

When the method MT1 is implemented to etch the substrate W shown in FIG. 7, the adsorption layer AB is formed on the recess RS in step ST2. The adsorption layer AB may be located on the sidewalls and the bottom of the recess RS. The adsorption layer AB may be located on the pair of first sidewalls SW1 and the pair of second sidewalls SW2.

In step ST4, the pair of first sidewalls SW1 and the pair of second sidewalls SW2 are etched. The etching enlarges the recess RS in the XY plane including the first direction X and the second direction Y (refer to the recess RS indicated by the dashed line in FIG. 7). The pair of second sidewalls SW2 are each etched by an etching amount YEA greater than an etching amount XEA of each of the pair of first sidewalls SW1. This may be caused by a greater flux of the ions IN incident on each of the pair of second sidewalls SW2 than the flux of the ions IN incident on each of the pair of first sidewalls SW1.

Various experiments conducted for evaluating the method MT1 will now be described. The experiments described below are not intended to limit one or more embodiments of the present disclosure.

### First Experiment

In the first experiment, a substrate was first placed on a substrate support in a chamber in a plasma processing device (step ST1). The substrate had a SiO₂ film on its surface. Then, a first process gas including an HF gas and an Ar gas was supplied onto the substrate without plasma generation (step ST2). Step ST2 was performed for a duration of 60 seconds. An argon gas was then supplied into the chamber to purge the internal space of the chamber (step ST3). Step ST3 was performed for a duration of 30 seconds. Plasma generated from the Ar gas was then provided to the substrate while an electrical bias was being provided to the substrate support (step ST4). Step ST4 was performed for a duration of 10 seconds. Steps ST2 to ST4 were then repeated to allow each of steps ST2 to ST4 to be performed three times or for three cycles (step ST5). The temperature of the substrate support was −5° C. in steps ST2 to ST5.

### Second Experiment

A second experiment was conducted in the same manner as the first experiment except that step ST5 was performed for 10 cycles.

### Third Experiment

A third experiment was conducted in the same manner as the first experiment except that step ST5 was performed for 20 cycles.

### Fourth Experiment

A fourth experiment was conducted in the same manner as the first experiment except that the substrate included a SiN film in place of the SiO₂ film.

### Fifth Experiment

A fifth experiment was conducted in the same manner as the fourth experiment except that step ST5 was performed for 10 cycles.

### Sixth Experiment

A sixth experiment was conducted in the same manner as the fourth experiment except that step ST5 was performed for 20 cycles.

### Seventh Experiment

A seventh experiment was conducted in the same manner as the second experiment except that the substrate included a photoresist film in place of the SiO₂ film. Step ST5 was performed for 10 cycles.

### Eighth Experiment

An eighth experiment was conducted in the same manner as the seventh experiment except that step ST5 was performed for 20 cycles.

### Ninth Experiment

A ninth experiment was conducted in the same manner as the second experiment except that the substrate included a polysilicon film in place of the SiO₂ film. Step ST5 was performed for 10 cycles.

### Tenth Experiment

A tenth experiment was conducted in the same manner as the ninth experiment except that step ST5 was performed for 20 cycles.

### Eleventh Experiment

An eleventh experiment was conducted in the same manner as the third experiment except that the substrate included a WSi film in place of the SiO₂ film. Step ST5 was performed for 20 cycles.

### First Experimental Results

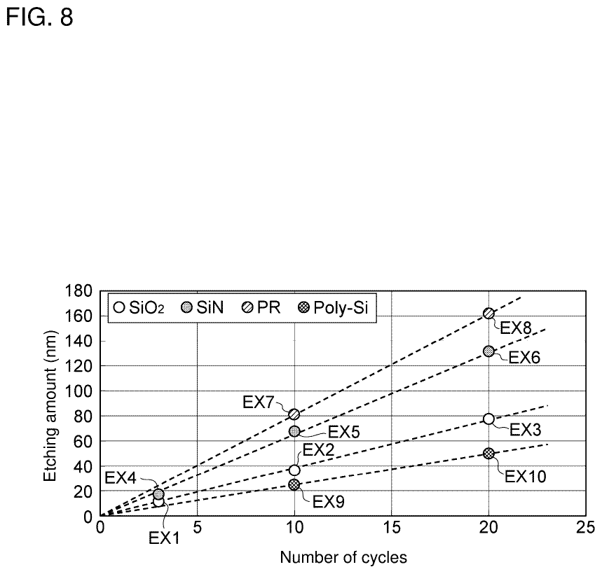

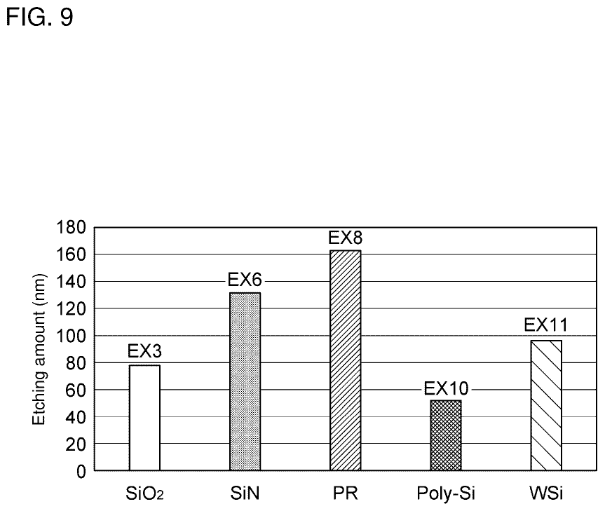

The etching amount of the film included in the substrate was measured in the first to eleventh experiments. The results are shown in FIGS. 8 and 9. In FIGS. 8 and 9, EX1 to EX11 indicate the respective measurement results of the first to eleventh experiments. As shown in FIG. 8, the results reveal that the etching amount increases in proportion to the number of cycles in each film in the first to tenth experiments. As shown in FIG. 9, the results also reveal that the photoresist (PR) film, the SiN film, the WSi film, the SiO₂ film, and the polysilicon (poly-Si) film are etched more easily in this order.

### Twelfth Experiment

A twelfth experiment was conducted in the same manner as the first experiment except that step ST2 was performed for a duration of 180 seconds and steps ST3 to ST5 were not performed.

### Thirteenth Experiment

A thirteenth experiment was conducted in the same manner as the first experiment except that step ST4 was performed for a duration of 30 seconds and steps ST2, ST3, and ST5 were not performed.

### Fourteenth Experiment

A fourteenth experiment was conducted in the same manner as the twelfth experiment except that the substrate included a SiN film in place of the SiO₂ film.

### Fifteenth Experiment

A fifteenth experiment was conducted in the same manner as the thirteenth experiment except that the substrate included a SiN film in place of the SiO₂ film.

### Second Experimental Results

The etching amount of the film included in the substrate was measured in each of the twelfth to fifteenth experiments. All the etching amounts were less than or equal to 5 nm. The results reveal that performing either step ST2 or step ST4 alone does not facilitate etching.

### Sixteenth Experiment

A sixteenth experiment was conducted in the same manner as the second experiment except that a CF₄ gas was used in place of the HF gas in step ST2. The substrate included a SiO₂ film.

### Seventeenth Experiment

A seventeenth experiment was conducted in the same manner as the fifth experiment except that a CF₄ gas was used in place of the HF gas in step ST2. The substrate included a SiN film.

### Eighteenth Experiment

An eighteenth experiment was conducted in the same manner as the seventh experiment except that a CF₄ gas was used in place of the HF gas in step ST2. The substrate included a photoresist film.

### Nineteenth Experiment

A nineteenth experiment was conducted in the same manner as the ninth experiment except that a CF₄ gas was used in place of the HF gas in step ST2. The substrate included a polysilicon film.

### Third Experimental Results

The etching amount of the film included in the substrate was measured in each of the sixteenth to nineteenth experiments. Most of the etching amounts were 0 nm. The results reveal that performing step ST2 without the HF gas does not facilitate etching.

### Duration of Step ST2

The etching was performed in the same manner as in the second or fifth experiment except that the duration of step ST2 was changed to 10, 30, or 90 seconds, and the etching amount of the film included in the substrate was measured. The etching amount was larger for longer durations of step ST2 up to 60 seconds. When step ST2 was performed for a duration longer than 60 seconds, the etching amount remained substantially unchanged although step ST2 was performed for a longer duration. This indicates that the formation of an adsorption layer or a reaction layer of the HF gas is automatically stopped through a self-limited reaction.

### Duration of Step ST4

The etching was performed in the same manner as in the second or fifth experiment except that the duration of step ST4 was changed to 2, 5, or 20 seconds, and the etching amount of the film included in the substrate was measured. The etching amount was larger for longer durations of step ST4 up to 10 seconds. When step ST4 was performed for a duration longer than 10 seconds, the etching amount remained substantially unchanged although step ST4 was performed for a longer duration. This indicates that etching is automatically stopped when the adsorption layer or the reaction layer of the HF gas is depleted.

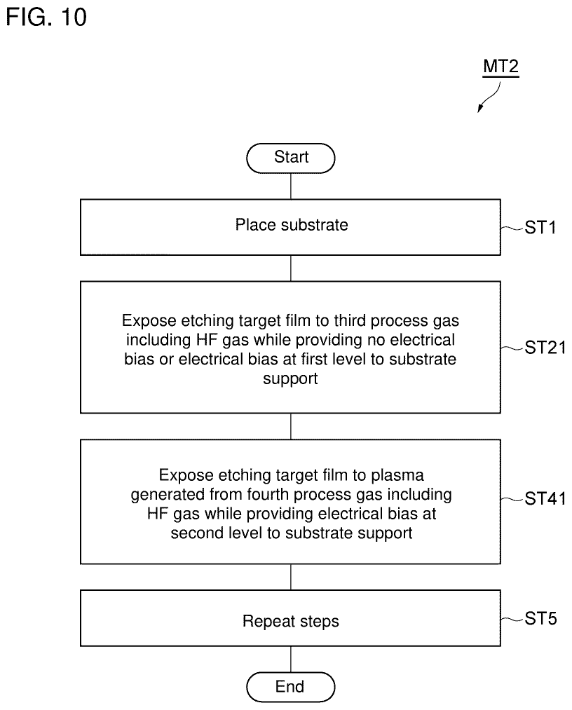

FIG. 10 is a flowchart of an etching method according to one exemplary embodiment. An etching method MT2 shown in FIG. 10 (hereafter referred to as a method MT2) may be implemented by the plasma processing device 1 according to the above embodiment. The method MT2 may be implemented for the substrate W in FIG. 4.

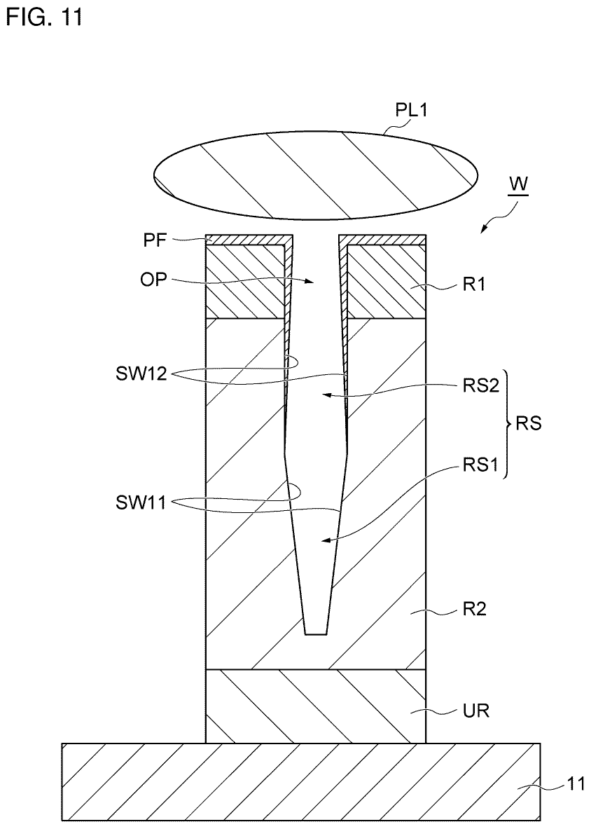

The method MT2 implemented by the plasma processing device 1 according to the above embodiment to process the substrate W will now be described by way of example with reference to FIGS. 4 and 10 to 13. FIGS. 11 to 13 are each a cross-sectional view of a substrate undergoing a step in the etching method according to the exemplary embodiment. The components of the plasma processing device 1 are controlled by the controller 2 to allow the plasma processing device 1 to implement the method MT2. With the method MT2, the substrate W is processed on the substrate support 11 located in the plasma processing chamber 10 as shown in FIG. 2.

As shown in FIG. 10, the method MT2 may include steps ST1, ST21, ST41, and ST5. Steps ST1, ST21, ST41, and ST5 may be performed sequentially. The method MT2 may not include step ST5.

### Step ST1

In step ST1, the substrate W shown in FIG. 4 is placed on the substrate support 11 in the plasma processing chamber 10. As shown in FIG. 11, the second portion R2 is then etched with plasma PL1 generated from a process gas through the opening OP in the first portion R1. The substrate W on the substrate support 11 thus includes the second portion R2 including at least one recess RS. The recess RS may include a first part RS1 and a second part RS2 above the first part RS1. The first part RS1 may include first sidewalls SW11. The first part RS1 may include the bottom of the recess RS. The second part RS2 may include second sidewalls SW12. The second part RS2 may include the upper end of the recess RS. The first part RS1 in the recess RS may have a CD gradually decreasing from the upper end to the lower end of the first part RS1. The process gas for generating the plasma PL1 may include a fluorine-containing gas. Examples of the fluorine-containing gas include a fluorocarbon gas, a hydrofluorocarbon gas, and a hydrogen fluoride gas.

Each second sidewall SW12 may include a protective film PF. The protective film PF may be located on the first portion R1. The protective film PF may be formed simultaneously with the recess RS or after the recess RS is formed. When the process gas includes a fluorocarbon gas or a hydrofluorocarbon gas, the recess RS and the protective film PF may be formed simultaneously. In this case, the protective film PF contains carbon and fluorine. When the process gas includes a hydrogen fluoride gas, the recess RS may be formed without the protective film PF. In this case, the protective film PF may be formed by, for example, atomic layer deposition (ALD) or CVD after the recess RS is formed.

### Step ST21

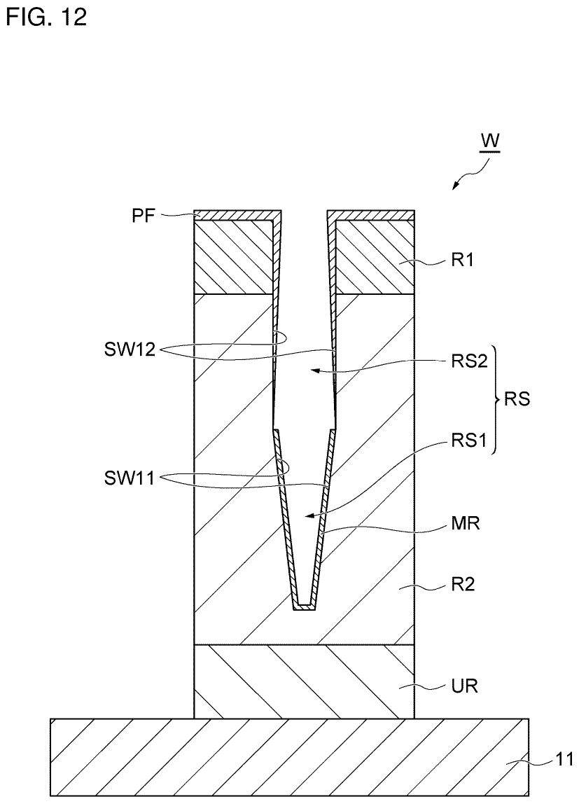

Step ST21 may be performed in the same manner as step ST2 in the method MT1. In step ST21, the second portion R2 is exposed to a third process gas including a hydrogen fluoride gas while no electrical bias or an electrical bias at a first level is being provided to the substrate support 11 as shown in FIG. 12. The third process gas may be the same as the process gas used in step ST1. The third process gas may further include a fluorocarbon gas or a hydrofluorocarbon gas. In step ST21, plasma may not be generated from the third process gas. In step ST21, the surface of each first sidewall SW11 may be modified as shown in FIG. 12. Thus, a modification layer MR is formed on the surface of the first sidewall SW11. When the protective film PF is formed on the second sidewall SW12, the modification layer MR is not formed on a portion of the surface of the second sidewall SW12 covered with the protective film PF. The modification layer MR may be the adsorption layer AB shown in FIG. 5.

### Step ST41

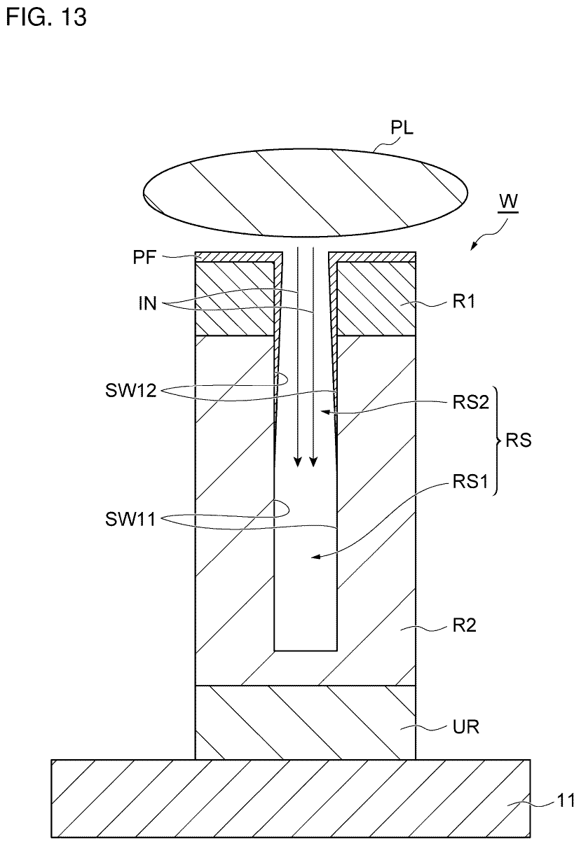

Step ST41 may be performed in the same manner as step ST4 in the method MT1. In step ST41, the second portion R2 is exposed to the plasma PL generated from a fourth process gas including a hydrogen fluoride gas while an electrical bias at a second level is being provided to the substrate support 11. The fourth process gas may be the same as the third process gas. The fourth process gas may further include a fluorocarbon gas or a hydrofluorocarbon gas. The second level at which the electrical bias is provided to the substrate support 11 in step ST41 is greater than the first level at which the electrical bias is provided to the substrate support 11 in step ST21. In step ST41, the surface of each first sidewall SW11 (modification layer MR) modified in step ST21 may be removed as shown in FIG. 13. The first sidewalls SW11 are thus etched.

### Step ST5

In step ST5, a cycle including steps ST21 and ST41 is repeated. Each cycle may further include an etching process included in step ST1 before step ST21.

The hydrogen fluoride gas may be continuously supplied into the plasma processing chamber 10 during steps ST21 and ST41. The hydrogen fluoride gas may be continuously supplied into the plasma processing chamber 10 throughout all the above cycles.

The above method MT2 allows the modification layer MR to be formed on the first part RS1 near the bottom of the recess RS in step ST21. In step ST41, this facilitates etching of the first part RS1 near the bottom of the recess RS. This increases the etching rate of the recess RS with a high aspect ratio. The first sidewalls SW11 can be etched in step ST41 to increase the CD of the bottom of the recess RS.

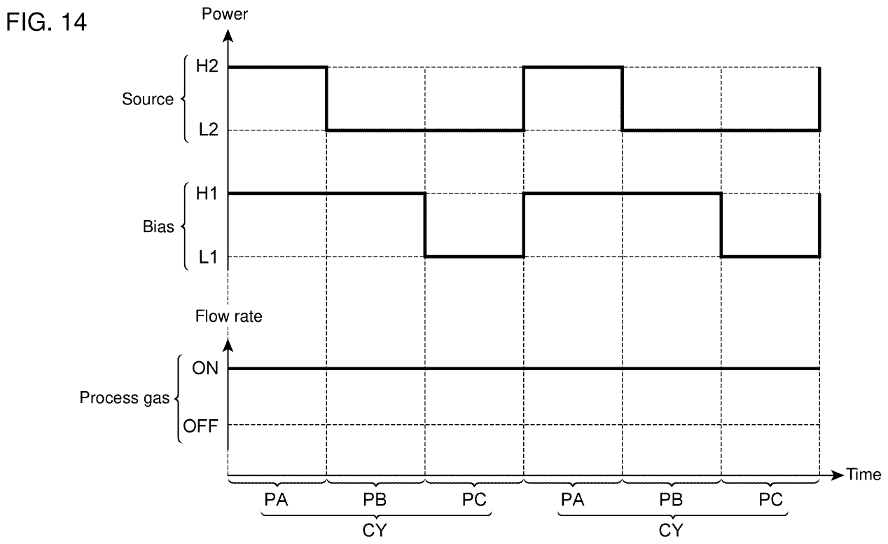

FIG. 14 is a timing chart of changes in power and the process gas supplied to the plasma processing device over time in an example. The timing chart is associated with steps ST1, ST21, ST41, and ST5. The plasma processing device 1 may receive source power and bias power. The source power may be RF power HF provided to an opposing electrode (upper electrode). The bias power may be RF power LF or a DC bias provided to an electrode in the body 111 in the substrate support 11.

As shown in FIG. 14, the source power and the bias power may be applied periodically in cycles CY. The cycle CY may include a first period PA, a second period PB, and a third period PC. The second period PB is subsequent to the first period PA. The third period PC is subsequent to the second period PB. The first period PA and the second period PB in the first cycle CY correspond to the etching process included in step ST1. In the etching process included in step ST1, the recess RS may be formed as shown in FIG. 11. The third period PC corresponds to step ST21. In step ST21, the modification layer MR may be formed as shown in FIG. 12. The first period PA and the second period PB subsequent to the third period PC correspond to step ST41. In step ST41, the first sidewalls SW11 may be etched as shown in FIG. 13. The third period PC in the second cycle CY and a subsequent period correspond to step ST5.

In the first period PA, the power level of the source power may be maintained at a level H2, and the power level of the bias power may be maintained at a level H1. The level H1 is lower than the level H2. In the second period PB, the power level of the source power may be maintained at a level L2, and the power level of the bias power may be maintained at the level H1. The level L2 is lower than the level H2. The level L2 may be 0 W. In the third period PC, the power level of the source power may be maintained at the level L2, and the power level of the bias power may be maintained at a level L1. The level L1 is lower than the level H1. The level L1 may be 0 W.

The substrate support 11 may receive a DC bias in place of the RF power LF as the electrical bias. The DC bias may include a voltage pulse. When the electrical bias is bias RF power, the level of the electrical bias is a power level (effective value) of the bias RF power. When the electrical bias includes a voltage pulse, the level of the electrical bias is an absolute value of a negative voltage level of the voltage pulse.

As shown in FIG. 14, the process gas supplied to the plasma processing device may be supplied continuously throughout all the cycles CY. The process gas may include, for example, a fluorocarbon gas, a hydrofluorocarbon gas, and a hydrogen fluoride gas.

Although various exemplary embodiments have been described above, the embodiments are not restrictive, and various additions, omissions, substitutions, and changes may be made. The components in the different embodiments may be combined to form another embodiment.

Various exemplary embodiments E1 to E19 included in the present disclosure will now be described.

### E1

An etching method, comprising:
(a) placing a substrate on a substrate support in a chamber;
(b) exposing the substrate to a first process gas including a hydrogen fluoride gas; and
(c) exposing, after (b), the substrate to plasma generated from a second process gas while providing an electrical bias to the substrate support, the second process gas including at least one inert gas selected from the group consisting of a noble gas and a nitrogen gas.

The etching method according to E1 can increase the etching rate of the substrate.

### E2

The etching method according to E1, further comprising:
(d) repeating (b) and (c).

### E3

The etching method according to E1 or E2, wherein
(b) is performed for a duration of 0.1 to 100 seconds.

### E4

The etching method according to any one of E1 to E3, wherein
(c) is performed for a duration of 0.1 to 100 seconds.

### E5

The etching method according to any one of E1 to E4, wherein
the substrate comprises at least one selected from the group consisting of silicon, carbon, and a metal.

### E6

The etching method according to E5, wherein
the substrate comprises at least one silicon-containing material selected from the group consisting of silicon oxide, silicon nitride, silicon oxynitride, and polysilicon.

### E7

The etching method according to E5, wherein
the substrate comprises at least one carbon-containing material selected from the group consisting of a photoresist and amorphous carbon.

### E8

The etching method according to E5, wherein the substrate comprises at least one metal selected from the group consisting of tungsten, molybdenum, and titanium.

### E9

The etching method according to any one of E1 to E8, wherein
the substrate includes a first portion and a second portion below the first portion, the first portion comprises a first material and has an opening, and the second portion comprises a second material different from the first material.

In this case, clogging of the opening is reduced during (b).

### E10

The etching method according to E9, wherein
the second material includes at least one selected from the group consisting of silicon, carbon, and a metal.

### E11

The etching method according to E9 or E10, wherein
the first material includes a metal other than tungsten, molybdenum, and titanium.

### E12

The etching method according to any one of E1 to E11, further comprising:
(e) purging an internal space of the chamber between (b) and (c).

### E13

The etching method according to any one of E1 to E12, wherein
(b) includes controlling a temperature of the substrate support to be in a range of −10 to 80° C.

### E14

The etching method according to any one of E1 to E13, wherein
the substrate includes an etching target film including at least one recess,
the at least one recess includes a pair of first sidewalls facing each other with a first width between the pair of first sidewalls in a first direction and a pair of second sidewalls facing each other with a second width between the pair of second sidewalls in a second direction perpendicular to the first direction, and the second width is greater than the first width, and
(c) includes etching the pair of first sidewalls and the pair of second sidewalls, and the pair of second sidewalls are etched by a greater degree than the pair of first sidewalls.

### E15

An etching method, comprising:
(a) placing, on a substrate support in a chamber, a substrate including an etching target film including at least one recess;
(b) exposing the etching target film to a third gas including a hydrogen fluoride gas while providing, to the substrate support, no electrical bias or an electrical bias at a first level; and
(c) exposing, after (b), the etching target film to plasma generated from a fourth process gas including a hydrogen fluoride gas while providing, to the substrate support, an electrical bias at a second level greater than the first level.

### E16

The etching method according to E15, wherein
the hydrogen fluoride gas is continuously supplied into the chamber during (b) and (c).

### E17

The etching method according to E15 or E16, wherein
a cycle including (b) and (c) is repeated.

### E18

The etching method according to any one of E15 to E17, wherein
the recess includes a first part and a second part above the first part, the first part includes a first sidewall, and the second part includes a second sidewall,
(b) includes modifying a surface of the first sidewall, and
(c) includes removing the modified surface of the first sidewall.

### E19

A plasma processing device, comprising:
a chamber;
a substrate support configured to support a substrate in the chamber;
a gas supply configured to supply a first process gas and a second process gas into the chamber, the first process gas including a hydrogen fluoride gas, the second process gas including at least one inert gas selected from the group consisting of a noble gas and a nitrogen gas;
a plasma generator configured to generate plasma from the second process gas in the chamber;
a power supply configured to provide an electrical bias to the substrate support; and
a controller configured to control the gas supply, the plasma generator, and the power supply to perform operations including
   (b) exposing the substrate to the first process gas, and
   (c) exposing, after (b), the substrate to the plasma generated from the second process gas while providing the electrical bias to the substrate support.

Various exemplary embodiments according to the present disclosure have been described by way of example, and various changes may be made without departing from the scope and spirit of the present disclosure. The exemplary embodiments described above are thus not restrictive, and the true scope and spirit of the present disclosure are defined by the appended claims.

What is claimed is:

1. An etching method, comprising:
placing a substrate on a substrate support in a chamber;
first exposing the substrate to a first process gas including a hydrogen fluoride gas; and
second exposing, after the first exposing, the substrate to plasma generated from a second process gas while providing an electrical bias to the substrate support, the second process gas including at least one inert gas selected from the group consisting of a noble gas and a nitrogen gas.

2. The etching method according to claim 1, further comprising:
repeating the first exposing and the second exposing.

3. The etching method according to claim 1, wherein
the first exposing is performed for a duration of 0.1 to 100 seconds.

4. The etching method according to claim 1, wherein
the second exposing is performed for a duration of 0.1 to 100 seconds.

5. The etching method according to claim 1, wherein
the substrate comprises at least one selected from the group consisting of silicon, carbon, and a metal.

6. The etching method according to claim 5, wherein
the substrate comprises at least one silicon-containing material selected from the group consisting of silicon oxide, silicon nitride, silicon oxynitride, and polysilicon.

7. The etching method according to claim 5, wherein
the substrate comprises at least one carbon-containing material selected from the group consisting of a photoresist and amorphous carbon.

8. The etching method according to claim 5, wherein
the substrate comprises at least one metal selected from the group consisting of tungsten, molybdenum, and titanium.

9. The etching method according to claim 1, wherein
the substrate includes a first portion and a second portion below the first portion, the first portion comprises a first material and has an opening, and the second portion comprises a second material different from the first material.

10. The etching method according to claim 9, wherein
the second material includes at least one selected from the group consisting of silicon, carbon, and a metal.

11. The etching method according to claim 9, wherein
the first material includes a metal other than tungsten, molybdenum, and titanium.

12. The etching method according to claim 1, further comprising:
purging an internal space of the chamber between the first exposing and the second exposing.

13. The etching method according to claim 1, wherein
the first exposing includes controlling a temperature of the substrate support to be in a range of −10 to 80° C.

14. The etching method according to claim 1, wherein
the substrate includes an etching target film including at least one recess,
the at least one recess includes a pair of first sidewalls facing each other with a first width between the pair of first sidewalls in a first direction and a pair of second sidewalls facing each other with a second width between the pair of second sidewalls in a second direction perpendicular to the first direction, and the second width is greater than the first width, and
the second exposing includes etching the pair of first sidewalls and the pair of second sidewalls, and the pair of second sidewalls are etched by a greater degree than the pair of first sidewalls.

15. An etching method, comprising:
placing, on a substrate support in a chamber, a substrate including an etching target film including at least one recess;
first exposing the etching target film to a third gas including a hydrogen fluoride gas while providing, to the substrate support, no electrical bias or an electrical bias at a first level; and
second exposing, after the first exposing, the etching target film to plasma generated from a fourth process gas including a hydrogen fluoride gas while providing, to the substrate support, an electrical bias at a second level greater than the first level.

16. The etching method according to claim 15, wherein
the hydrogen fluoride gas is continuously supplied into the chamber during the first exposing and the second exposing.

17. The etching method according to claim 15, wherein
a cycle including the first exposing and the second exposing is repeated.

18. The etching method according to claim 15, wherein
the recess includes a first part and a second part above the first part, the first part includes a first sidewall, and the second part includes a second sidewall,
the first exposing includes modifying a surface of the first sidewall, and
the second exposing includes removing the modified surface of the first sidewall.

19. A plasma processing device, comprising:
a chamber;
a substrate support configured to support a substrate in the chamber;
a gas supply configured to supply a first process gas and a second process gas into the chamber, the first process gas including a hydrogen fluoride gas, the second process gas including at least one inert gas selected from the group consisting of a noble gas and a nitrogen gas;
a plasma generator configured to generate plasma from the second process gas in the chamber;
a power supply configured to provide an electrical bias to the substrate support; and
a circuitry configured to control the gas supply, the plasma generator, and the power supply to perform operations including first exposing the substrate to the first process gas, and
second exposing, after the first exposing, the substrate to the plasma generated from the second process gas while providing the electrical bias to the substrate support.
